(19) United States
(12) Patent Application Publication
(10) Pub. No.: US 2010/0109130 A1
(43) Pub. Date: May 6, 2010

(54) METHOD OF FORMING AN OXIDE THIN FILM

(75) Inventors: Nicola Alessandro Alessandro Pinna, Aveiro (PT); Erwan Rauwel, Aveiro (PT)

Correspondence Address: HOWREY LLP-EU, C/O IP DOCKETING DEPARTMENT, 2941 FAIRVIEW PARK DR., SUITE 200, FALLS CHURCH, VA, 22042, US

(73) Assignee: UNIVERSITY OF AVEIRO, AVEIRO (PT)

(21) Appl. No.: 12/526,794

(22) PCT Filed: Feb. 13, 2008
(86) PCT No.: PCT/EP08/51745

§ 371 Date: Aug. 12, 2009

(30) Foreign Application Priority Data
Feb. 13, 2007 (GB) 0702759.2
Feb. 14, 2007 (US) 60901084

(51) Int. Cl. H01L 29/51; H01L 21/31; H01L 21/28

(52) U.S. Cl. 257/632; 438/778; 438/585; 257/E21.24; 257/E21.19; 257/E29.162

(57) ABSTRACT

A thin oxide film is formed by atomic layer deposition (ALD) onto a substrate by exposing the substrate to a first precursor comprising a metal organic alkoxide or amide or heteroleptic derivatives thereof and subsequently exposing the substrate to a second precursor comprising an ALD compatible carboxylic acid or carboxyl acid derivative compound. The sequential exposure to the first and second precursors may be repeated until a sufficient film thickness of an oxide of the metal has been deposited on the substrate. This process allows growth of an oxide thin film or nanostructure, on any suitable substrate. It permits formation of a high-κ dielectric oxide thin film on the substrate with similar dielectric properties to a much thinner SiO₂ film. Furthermore, the films grown can exhibit very good structural and physical properties. The process also provides high self-control of thin film growth with high reproducibility and reliability. In particular, the films can be synthesized with excellent similarity even on uneven surfaces and present a very smooth surface finish with very low roughness.

### BACKGROUND OF THE INVENTION

1. Field of the Invention

The invention relates generally to oxide thin film synthesis and in particular to a new atomic layer deposition (ALD) procedure supported by a non-aqueous reaction. The thin films of the invention may be deposited on all forms of substrates, including flat, nano-structured, particulate like, patterned and the like. The invention thus also relates to components and devices incorporating such thin films for use in diverse applications including but not limited to, Complementary Metal Oxide Semiconductor (CMOS) technology, Metal Insulator Metal (MIM) capacitors and Dynamic Random Access Memory (DRAM).

2. Description of the Related Art

Extensive miniaturization of integrated circuits and the demand for increased performance has spurred on the search for dielectric oxides to replace SiO₂ in future silicon-based microelectronic applications. At present, the thickness of the SiO₂ film which would be needed to achieve the required capacitance for the next generations of transistors and other components is too low from the point of view of current leakage. This reduced thickness induces a high tunneling current (commonly called leakage current) which can affect the functioning of the component.

In order to reduce the leakage current and to obtain a capacitance complying with future requirements, the SiO₂ thin film should be replaced by a material having a greater dielectric function (High-κ dielectric). Several high-κ dielectric films have been investigated as alternatives to the SiO₂ gate dielectric. A higher dielectric constant, typically around 20, allows the use of a thicker gate dielectric to drastically reduce the leakage current. Numerous promising candidates which present higher dielectric constants than SiO₂ have been studied in the aim of solving this problem including hafnium oxide and hafnium silicate. These structures have not yet been extensively studied but have been found to have inferior properties compared with SiO₂, such as a tendency to crystallize and a high density of electronic defects.

A presently favoured procedure for forming oxide thin films is Atomic Layer Deposition (ALD). ALD is a form of chemical vapour deposition (CVD) in which the reaction between precursor materials is separated into two half-reactions. In this manner, the precursor materials are kept separate during the reaction and film growth can be self-limiting. A first precursor material is introduced into a reaction chamber under appropriate temperature and (generally) high vacuum conditions where it reacts to form a unitary molecular layer on the surface of the substrate. After purging of the chamber to remove excess of the first precursor material, the second precursor material is introduced. On reaction at the substrate surface, a further molecular layer is formed or the existing layer is transformed. Since the process is based on surface reactions, atomic scale deposition control is possible. By keeping the precursors separate throughout the coating process, atomic layer control of film growth can be obtained down to ˜0.1 angstroms per layer. By repeating the process, a film having the desired thickness can be produced.

Current procedures using ALD to deposit high-κ thin film have not however always provided the desired result. In the majority of cases, formation or growth of an interfacial layer between the Si substrate and the high-κ thin film takes place during deposition. Among the suggested materials, HfO₂ is considered as a serious alternative for the gate dielectric due to its high dielectric constant (17-26) and wide gap (≅5.68 eV). It is one of the most promising candidates to replace SiO₂ in microelectronic applications such as CMOS technology, MIM capacitors and Flash memory applications. Nevertheless, at present, deposition of alternative metal oxide layers without interfacial SiO₂ layer growth has not been achieved in a satisfactory manner. This is currently believed to be one of the most important problems for CMOS technology applications.

Alternative procedures have been proposed to reduce SiO₂ layer growth. These procedures are however considerably more complex and relatively inefficient. At present, growth of an oxide on silicon without an interfacial SiO₂ layer has required Molecular Beam Epitaxy (MBE) techniques in an ultra high vacuum or the inclusion of an interfacial SiOₓN_{y} layer to prevent rapid growth of the interfacial SiO₂ layer. Current ALD or CVD processes use halides or metalorganic precursors (e.g. alkoxides, amides, diketonates). The use of halide precursors induces halide impurities in the films while the use of metalorganic precursors in Metal Oxide CVD (MOCVD) processes induces carbon impurities in the film. Carbons and halides can also have a significant and detrimental effect on the dielectric properties of the film. It is believed that they play an important role in lowering the dielectric properties and thus also the capacitance. In order to optimize the electrical properties of oxide thin films for microelectronics applications, carbon and halide impurities should preferably be minimized.

There is thus a particular need for improved manufacturing techniques that allow the efficient manufacture of semi-conductor components with greater capacitance and lower leakage currents. There is also a need to provide improved thin film quality using ALD techniques.

### BRIEF SUMMARY OF THE INVENTION

The present invention addresses these problems by providing a method of forming a thin film by atomic layer deposition (ALD) on a substrate by exposing the substrate to a first precursor comprising a metal organic alkoxide or amide or heteroleptic derivatives thereof and subsequently exposing the substrate to a second precursor comprising an ALD compatible carboxylic acid or carboxyl acid derivative compound. The sequential exposure to the first and second precursors may be repeated until a sufficient film thickness of an oxide of the metal has been deposited on the substrate. This process allows growth of an oxide thin film or nanostructure, on any suitable substrate. It permits formation of a high-κ dielectric oxide thin film on the substrate with similar dielectric properties to a much thinner SiO₂ film. Furthermore, films grown according to the present invention can exhibit very good structural and physical properties. The process also provides high self-control of thin film growth with high reproducibility and reliability. In particular, the films can be synthesized with excellent similarity even on uneven surfaces and present a very smooth surface finish with very low roughness.

In the present context, reference to ALD procedures is intended to include similar procedures including CVD, MOCVD, Atomic Layer Epitaxy (ALE) and the like, to the extent that they can be practised within the context of the present invention.

Reference to a substrate is intended to include any suitable structure on which it may be desired to form metal oxide layers according to the present invention, including but not limited to flat, nano-structured, particulate, porous and patterned surfaces. In the case of a silicon wafer the process allows growth of an oxide thin film presenting substantially no interfacial layer thickness of silicon dioxide. Other suitable substrates include but are not limited to semiconductors, metallic or insulating wafers, and nanostructures. Materials include silicon in all its forms, germanium, gallium compounds including gallium arsenide, gallium nitride and combinations and laminates of the above. Deposition could take place onto a raw substrate or onto one on which existing partial layers and architecture has already been established.

Reference to an alkoxide is intended to also include aryloxides, aralkyloxides, alkylaryloxides, combinations thereof, bimetallic alkoxides and alkoxide heteroleptic derivatives. The alkyl or aryl group may be saturated or unsaturated and preferably comprises between 1 and 20 carbon atoms. Reference to an amide is intended to also include arylamides, aralkylamides, alkylarylamides, combinations thereof, bimetallic amide and amide heteroleptic derivatives. Preferably, heteroleptic derivatives without halogen ligands may be used.

For a silicon substrate, deposition may take place at a temperature of 50-450° C., preferably in the range from 150-250° C. most preferably at around 175-200° C. The use of such relatively low temperatures makes the process especially suited for temperature sensitive components and allows deposition to be performed in a back-end manufacturing process after earlier manufacturing stages have been completed, in particular, after the metallic e.g. copper based connections have been formed. Lower temperature is also desirable for reasons of energy efficiency. For other substrates, similar deposition temperatures may be used although the skilled person will be aware that variations in these temperatures may be desirable in certain circumstances. When coating e.g. onto temperature sensitive substrates, temperatures as low as 10° C. may be desirable and low temperatures may be chosen in preference to increased reaction speed.

According to one aspect of the invention, deposition takes place under an atmosphere of inert gas, preferably nitrogen. In a preferred embodiment, the substrate is provided in a deposition chamber fed by a continuous stream of nitrogen. The method preferably also comprises purging of the deposition chamber with a substantially inert gas such as nitrogen between the successive exposures of the substrate to the first and second precursors. During the purge, delivery of the precursors may be discontinued.

According to a further aspect of the invention deposition may take place at a pressure of less than 20 torr, preferably less than 1 torr and most preferably around 0.2 ton. Such pressures are preferred values for the steady state pressure within the reaction chamber during deposition. Nevertheless, increased partial pressures may be observed when introducing pulses of the precursors into the reaction chamber. Momentary pressures of up to 760 torr (atmospheric pressure) may then be observed.

According to an important aspect the invention, the first precursor comprises a metal complex capable of forming a stable oxide. More preferably, the first precursor may comprise any suitable metal alkoxide or amide or heteroleptic derivatives thereof capable of being adsorbed onto the substrate. The compound may contain a metal selected from the group consisting of the transition metals (in particular Ti, Hf, Zr, Nb, Ta, Al, V, Y), the lanthanides (the 15 elements from Lanthanum to Lutetium), the alkaline earth metals (Mg, Ca, Sr and Ba) Sn, In, and Ga. In particular it has been shown that hafnium and similar metal salts catalyze the direct condensation of carboxylic acid with alcohols leading to the complete formation of esters. It is thus a further characteristic of the invention that exposure to the second precursor causes formation of an ester. While not wishing to be bound by theory, it is believed that films grown by the present process contain no or very low carbon impurities due to the ester elimination reaction which takes place during the growth process. In the case that a metal amide were used instead of an alkoxide, an N-acylation process would take place, leading to the elimination of an organic amide instead of an ester.

Most preferably, the second precursor comprises one or more carboxylic groups attached to hydrogen (HCOOH), an alkyl group (RCOOH), or an aryl group (ArCOOH). The group attached on the carboxylic function may be aliphatic or aromatic, saturated or unsaturated, substituted or unsubstituted and preferably comprises 1 to 20 carbon atoms.

According to a still further feature of the method, the sequential exposure to the first and second precursors is repeated until a metal oxide film of appropriate thickness has been achieved. For high performance electronic devices where increased capacitance is desirable a very thin layer may be desirable. For energy efficient devices where low leakage current is essential, greater thicknesses may be desirable. In the case of a high-κ dielectric such as HfO₂, a film thickness of 3 nm may have a greater capacitance than a 1.2 nm SiO₂ film, while exhibiting only one percent of the leakage current associated with the SiO₂ film.

A further characteristic of the invention is that the deposition may take place substantially without exposure to water. The procedure may be thus termed non-aqueous. By using a carboxylic acid based precursor, the use of water is no longer required and oxidation of silicon cannot take place. It is of course conceivable that further processes may be performed prior to or after the deposition in which water or water based substances are used.

According to a yet further aspect of the invention the method may further comprise finishing the component to form a micro-electronic device. The additional steps required to finish the device will depend upon the intended function and may be generally conventional. The skilled person will be well aware of these procedures and further description of such steps is believed unnecessary at this point. Most importantly, the deposition of the metal oxide film may take place at a back-end of the manufacture of the electronic component. Because the method of the invention may be carried out at relatively low temperatures, deposition of the oxide film may be carried out subsequent to the main manufacturing steps, without risking damage to the existing structures. In particular, it is noted that the copper circuitry that is frequently used for interconnection on such components is relatively sensitive to high temperatures. A low deposition temperature allows film formation subsequent to laying down such copper circuitry or similar temperature sensitive elements.

The invention also relates to a metal oxide thin film deposited onto a substrate according to the above defined processes. In particular it relates to a component comprising a substrate and a metal oxide film being substantially free of carbon and halide impurities, wherein the metal oxide film is intimately bonded to the substrate at an interface and substantially no silicon oxide is present at the interface when silicon is used as substrate. According to the present process the film generally presents no (or minimal) low-κ dielectric oxide at the interface between the high κ dielectric oxide and the substrate. This includes both SiO₂ and other silicates that have conventionally been formed during deposition processes using silicon as substrate.

The component according to the invention may be manufactured to form any appropriate Metal Oxide Semiconductor (MOS) device, in particular a CMOS micro-electronic device. Alternatively it could form a metal-insulator-metal (MIM) capacitor, in particular as part of a Dynamic Random Access Memory (DRAM) device. Nevertheless, it is also considered that such a metal oxide film could be provided in any appropriate micro-electronic device requiring metal oxide films which present no or very low carbon impurities and/or minimal interfacial layer growth of SiO₂.

### BRIEF DESCRIPTION OF THE DRAWINGS

The features and advantages of the invention will be appreciated upon reference to the following drawings, in which:

FIG. 1 is an example of a conventional NMOS device;

FIG. 2A is a section through the gate of FIG. 1;

FIG. 2B is a similar section to FIG. 2A through the gate of a device according to the invention;

FIG. 3 A shows reflectometry measurements on a HfO₂ film according to the invention without HF-last pre-treatment;

FIG. 3 B shows reflectometry measurements on a HfO₂ film according to the invention with HF-last pre-treatment;

FIG. 4 shows ALD deposition rates of HfO₂ at different temperatures

FIG. 5 shows reflectometry measurements on a TiO₂ film according to the invention formed using an acetic acid precursor;

FIG. 6 shows reflectometry measurements on a TiO₂ film according to the invention formed using a formic acid precursor;

FIG. 7 is an example of a carbon nanotube coated inside and outside by 10 nm of TiO₂; and

FIG. 8 is an example of a carbon nanotube coated inside and outside by 5 nm of HfO₂.

### DESCRIPTION OF ILLUSTRATIVE EMBODIMENTS

The following is a description of certain embodiments of the invention, given by way of example only and with reference to the drawings.

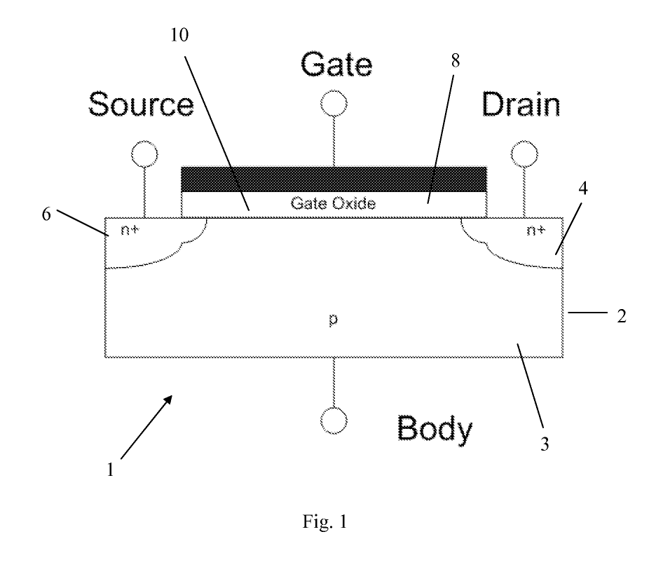

FIG. 1 shows a typical n-type Metal Oxide Semi-conductor (NMOS) 1 of the type that forms the basis in conventional CMOS technology. CMOS is a major class of integrated circuits and CMOS chips are present as microprocessor, microcontroller, static RAM, and other digital logic circuits. Over the past decade, CMOS technology has also been used for a wide variety of analogue circuits such as image sensors, data converters, and highly integrated transceivers for many types of communication. The NMOS 1 of FIG. 1 comprises a silicon substrate 2 having a main body 3 formed of lightly doped p-type silicon. Doped regions of n-type silicon form a drain 4 and source 6. The drain 4 and source 6 are relatively highly doped in relation to the body 3. On an upper surface of the substrate a SiO₂ gate oxide layer 8 is formed. A gate layer 10 of polysilicon material is formed over the gate oxide layer 8.

The two key dimensions related to the gate dielectric of a transistor are equivalent oxide thickness (EOT) and capacitive effective thickness (CET). The definitions for these dimensions are abstract, but they allow comparison as devices are scaled down and require changes in materials used for the gate dielectric and gate electrode. EOT is defined as the thickness of SiO₂ that would produce the same capacitance-voltage curve as that obtained from an alternate dielectric system. Because the dielectric constant of the material is seldom known with any certainty, the EOT must be determined from an electrical capacitance measurement. This provides a parameter that does not depend on other quantities (e.g., type of electrode, electrode work function, or substrate doping). CET is an effective thickness that depends on other quantities such as type of electrode, electrode work function, substrate doping, and gate voltage of measurement

In use, when a positive gate-source voltage is applied, it creates an n-channel at the surface of the p-region of the main body 3, just under the gate oxide layer 8, by depleting this region of holes. This channel extends between the source 6 and the drain 4, but current is conducted through it only when the gate potential is high enough to attract electrons from the source into the channel. When zero or negative voltage is applied between gate 10 and source 6, the channel disappears and no current can flow between the source 6 and the drain 4.

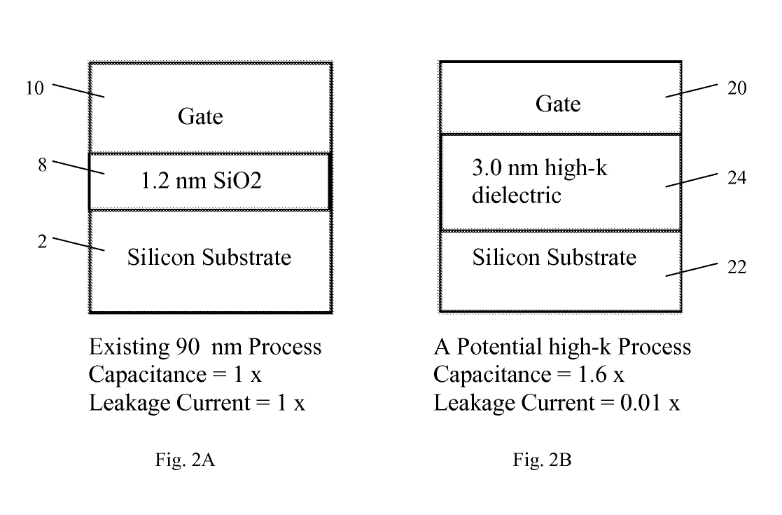

FIG. 2A shows a schematic view of the layers forming the gate region of the NMOS 1 of FIG. 1. The gate oxide layer 8 has a thickness of 1.2 nm, representing the spacing between the gate layer 10 and the substrate 2. This is the typical dimension of a 90 nm feature size device and represents standard production from around 2002 up to 2006.

FIG. 2B shows a schematic view of the layers forming the gate region in a device 20 according to the invention in which the SiO₂ gate oxide layer has been replaced with a HfO₂ gate oxide layer 22 having a thickness of 3.0 nm. Furthermore, the gate 24 itself is formed of a metal compound e.g. TiN, TaN, Pt, WN or another high-κ compatible material.

The structures of FIGS. 2A and 2B are compared in terms of equivalent performance and it is found that the high-κ model has an equivalent capacitance of 1.6 times the SiO₂ model. Of greater importance in this case, the leakage current of the high-κ model is just 0.01 or one hundredth of the value of that of the SiO₂ model.

The hafnium oxide layer of FIG. 2B is formed by esterification of a carboxylic acid. Commonly, in solution, a carboxylic acid is converted directly into an ester when heated with an alcohol in the presence of mineral acid (e.g. H₂SO₄, HCl) acting as a catalyst. This reaction is reversible and generally reaches equilibrium. In solution, the reversibility is a disadvantage for ester production. However, the equilibrium can be shifted by removing one of the products. In the case of ALD, the reaction takes place in gas phase and in a vacuum environment. According to an article by K. Ishihara, S. Ohara and H. Yamamoto entitled “Direct Condensation of Carboxylic Acids with Alcohols Catalyzed by Hafnium (IV) Salts”, Science, 2000, 290, 1140, it has been shown that hafnium and other metal salts catalyze the direct condensation of carboxylic acid with alcohols leading to the complete formation of esters. This characteristic of transition metal ions is now applied in order to produce oxide films by ALD. In an ALD cycle firstly the introduced metal precursor (e.g. alkoxide) forms a monolayer on the substrate. Secondly the adsorbed metal precursor reacts with the carboxylic acid, which is introduced as a pulse into the reaction chamber. Without wishing to be bound by theory, it is believed that the reaction proceeds by one of two mechanisms. Either the reaction produces a hydroxyl group at the surface of the freshly formed metal oxide layer under the elimination of the ester or alternatively it modifies the metal alkoxide replacing the alkoxy ligands by carboxylates under the elimination of the alcohol.

In order to avoid gas phase reactions caused by intermixing the precursor and the carboxylic acid, the reaction chamber is purged with pure carrier gas after each metal precursor or carboxylic acid pulse.

According to a first example, the schematic reaction at the surface of a metal oxide film (with a metal alkoxide as metal source) taking place during the carboxylic acid pulse are the following:

≡M-OR′+RCOOH→≡M-OH+RCOOR′ (A-1)

Or:

≡M-OR′+RCOOH→≡M-OOCR+R′OH (B-1)

Where: ≡ stands for any kind of ligand (OR′, OH, OOR, OM, etc.) coordinated to the metal M, R stands for H, CH₃ an alkyl group, etc. and R′ stands for CH₃ an alkyl group, etc.)

The inert gas purge after the reaction eliminates the excess of carboxylic acid and the products of the reaction. A new pulse of metal source will then react with the modified surface species (e.g. hydroxyl groups or carboxylates) leading to the formation of metal oxygen metal bond under the elimination of an alcohol or an ester, respectively. The reactions can then be schematized as below:

≡M-OH+M-OR′→≡M-O-M≡+R′OH (A-2)

≡M-OOCR+M-OR′→≡M-O-M≡+RCOOR′ (B-2)

The purge after the reaction eliminates the excess of metal source and the alcohol (A-2) or the ester (B-2) produced by the reaction.

During a complete ALD cycle, some additional secondary condensation reactions might occur: (i) the condensation of two surface adjacent M-OH groups forming a M-O-M bond under the elimination of water, (ii) the condensation of surface adjacent M-OH and alkoxy groups (M-OR′) under the elimination of alcohol (R′OH, similarly to reaction A-2), and (iii) the condensation of two surface adjacent alkoxy groups under the elimination of ether.

A new pulse of carboxylic acid will react with the surface species. The cycle is performed as many times as required in order to obtain the desired film thickness. By following the reaction path as described above there is substantially no carbon deposited on the film as may be confirmed by XPS analysis.

### EXAMPLE 1

### Deposition of 5 nm HfO₂ Thin Film at 200° C.

In an ALD reaction chamber one silicon substrate was introduced without treatment and one silicon substrate was cleaned by diluted HF-last solution (1 ml of methanol, 9 ml of water, and 0.75 ml of fluoric acid 40%) for 90 s just before introduction.

The two substrates were directly introduced in the preheated chamber (200° C.).

The hafnium tert-butoxide (Hf[OC(CH₃)₃]₄) source was heated at 40° C.

The acetic acid precursor source was heated at 35° C.

The pipelines between the sources of liquid precursor and the atomic layer deposition chamber were heated at 70° C.

The deposition chamber was heated at 200° C.

A continuous flow of 10 sccm of nitrogen was introduced into the deposition chamber during the whole process. Under these conditions the pressure in the deposition chamber was 0.17 torr.

The deposition of 5 nm HfO₂ film is made via 100 ALD cycles, each ALD cycle including:
Opening the hafnium precursor valve for 1.3 s in order to introduce the precursor in the deposition chamber
A pause of 20 s (under nitrogen flow).
A purge of 15 seconds (under nitrogen flow).
Opening the acetic acid valve for 0.02 s
A pause time is 20 s (under nitrogen flow).
A purge of 15 seconds (under nitrogen flow).

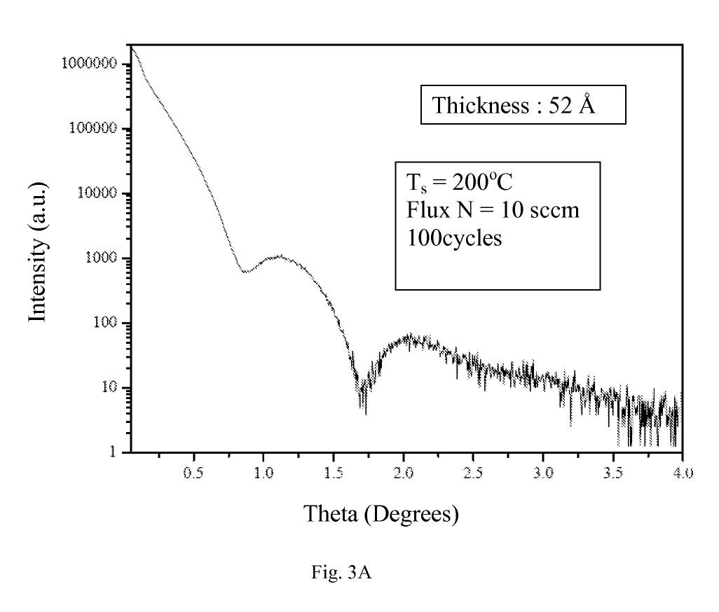

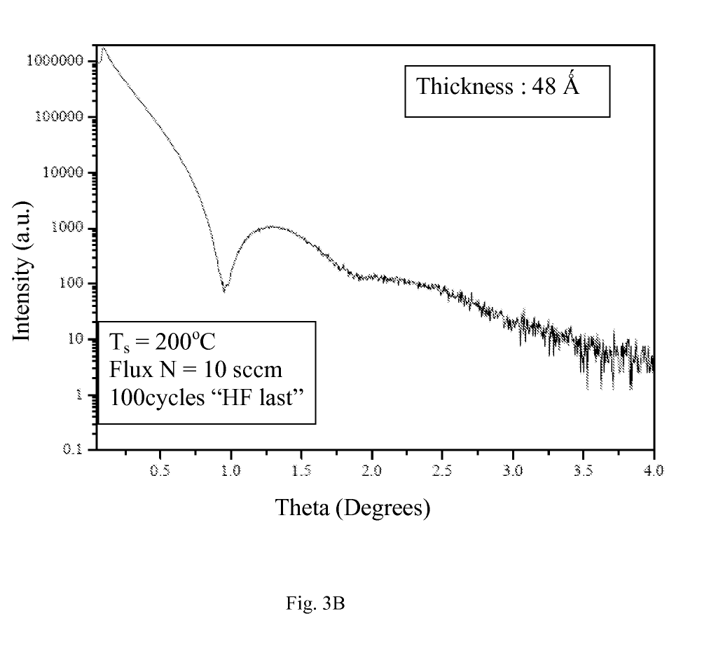

FIG. 3A shows reflectometry measurements of the HfO₂ film formed without prior HF-last treatment. FIG. 3B shows reflectometry measurements of the HfO₂ film formed with prior HF-last treatment. Both graphs show good surface roughness and similar grow rate for both films grown on treated and untreated silicon substrates.

### EXAMPLE 2

### Deposition Rate of HfO, Thin Film at Temperatures from 100-300° C.

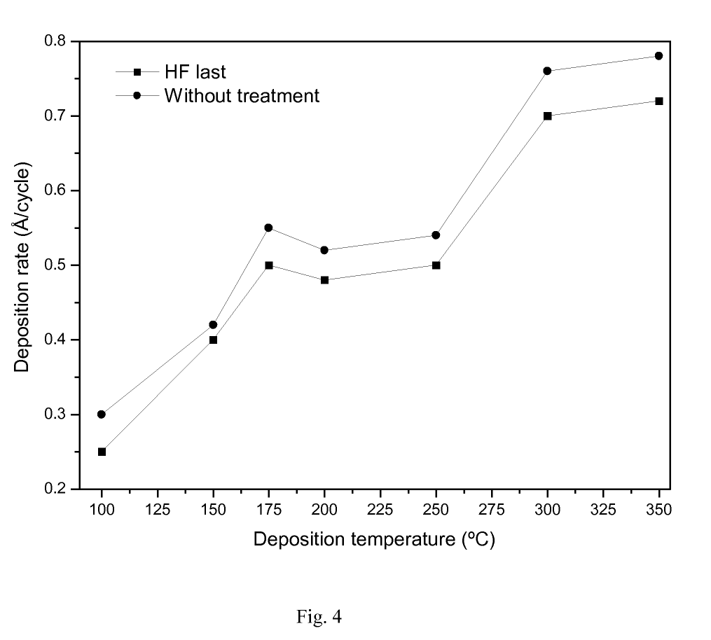

The experiment of Example 1 was repeated under deposition chamber temperatures of 100, 150, 175, 250 and 300° C. Other conditions remained the same. The deposition rates at different temperatures are depicted in FIG. 4, which shows a deposition plateau of 0.5 Å per cycle in the region from 175° C. to 250° C. Favourable deposition rates may be expected in this region, while avoiding the need for high temperatures in the deposition chamber.

### EXAMPLE 3

### Titanium Dioxide and Acetic Acid

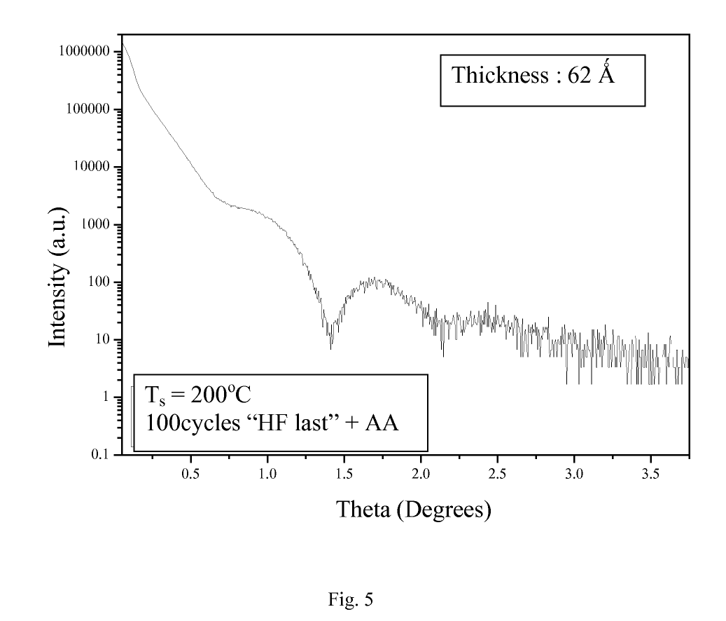

The experiment of Example 1 was repeated using acetic acid and using Ti isopropoxide in instead Hf tert-butoxide to form a TiO₂ gate oxide layer. The other experimental conditions were kept constant. Exemplary results were achieved in all cases. FIG. 5 shows reflectometry measurements of the TiO₂ film formed with prior HF-last treatment. The graph shows good surface roughness and a grow rate of 0.62 Å per cycle.

### EXAMPLE 4

### Titanium Dioxide and Formic Acid

The experiment of Example 3 was repeated using formic acid instead of acetic acid. The conditions were slightly different:

The titanium isopropoxide source was heated at 65° C.

The formic acid precursor source was heated at 40° C.

The deposition chamber was heated at 170° C.

A continuous flow of 50 sccm of nitrogen was introduced into the deposition chamber during the whole process.

The deposition of 7.6 nm TiO₂ film is made via 200 ALD cycles.

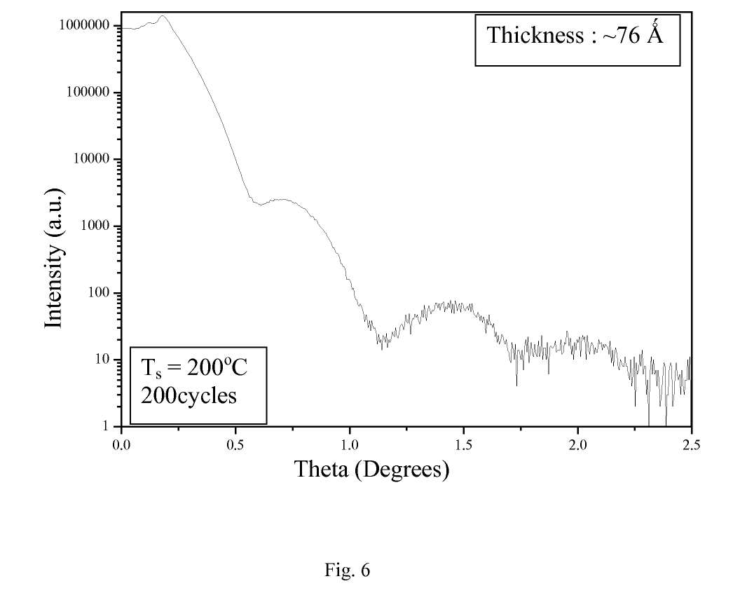

FIG. 6 shows reflectometry measurements of the TiO₂ film formed without prior HF-last treatment. The graph shows good surface roughness and a grow rate of 0.38 Å per cycle.

### EXAMPLE 5

### Titanium Dioxide and Acetic Acid on Carbon Nanotubes

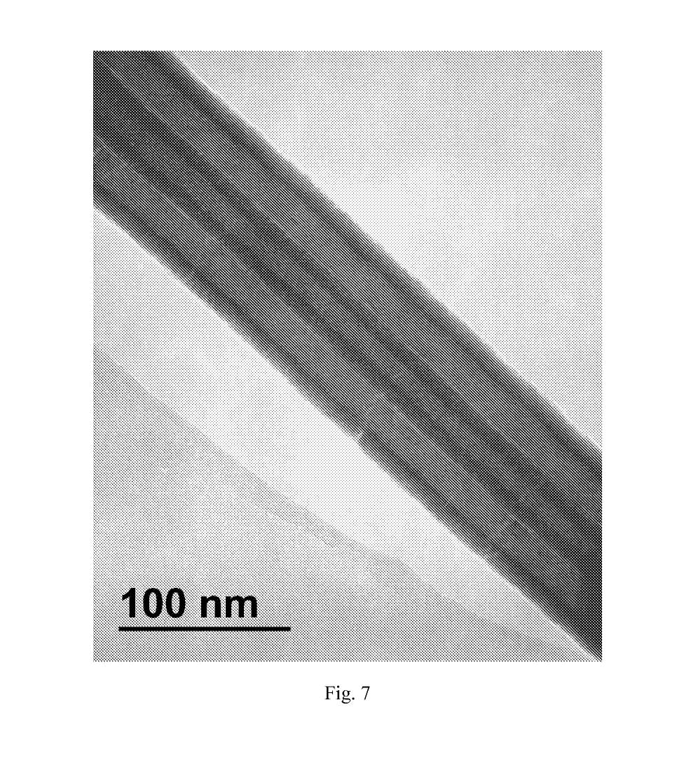

The experiment of Example 3 was repeated using carbon nanotubes instead of a silicon substrate for the deposition of TiO₂ onto and into them. The deposition of TiO₂ film is made via 200 ALD cycles. The other experimental conditions were kept constant. Exemplary results were achieved. FIG. 7 shows transmission electron microscopy data of the carbon nanotubes coated inside and outside by circa 10 nm of TiO₂.

### EXAMPLE 6

### Hafnium Dioxide and Acetic Acid on Carbon Nanotubes

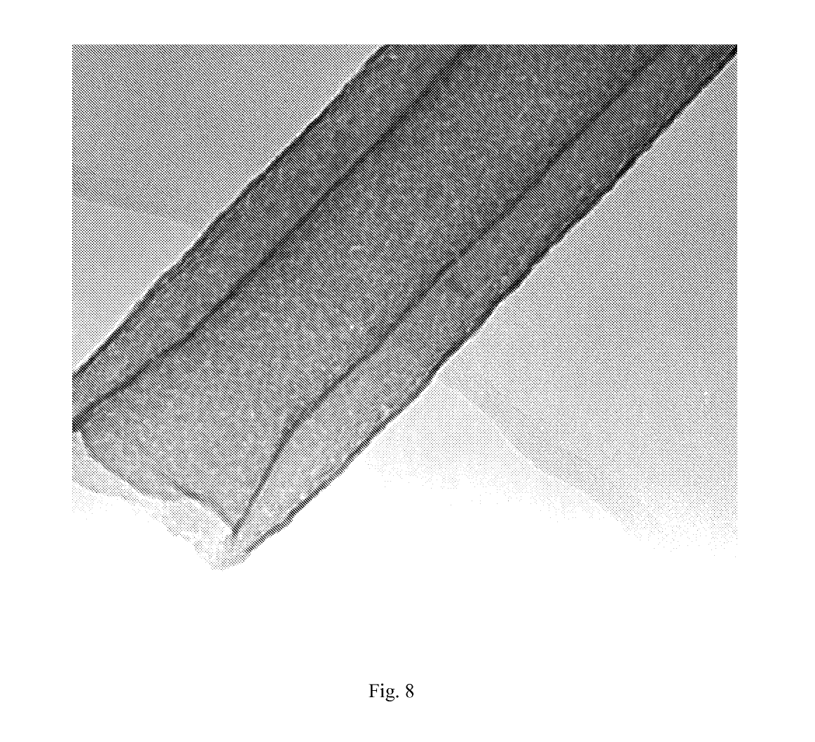

The experiment of Example 5 was repeated using Hf tert-butoxide instead of Ti isopropoxide to deposit HfO₂ onto and into the carbon nanotubes. The deposition of HfO₂ film is made via 150 ALD cycles. The other experimental conditions were kept constant. Exemplary results were achieved. FIG. 8 shows transmission electron microscopy data of the carbon nanotubes coated inside and outside by circa 5 nm of HfO₂.

Although the invention has been described in the context of electronic components, it could equally apply to coatings and films formed on any other suitable device. Such a precise deposition technique could therefore be used in the context of other coating technology for glasses and other materials for providing corrosion protection, anti-reflective surfaces, photo chromic surfaces and any other such desirable properties. Carbon nanotubes and other similar carbon structures are well known as chemically and physically stable materials with huge surface area and porosity. Thus, when coated with thin layers of metal oxides they can be used in a wide range of heterogeneous catalyst applications. They can also be used in resistive gas sensor devices due to the same properties. In a gas sensor the tube morphology can bring additional advantages such as enhanced sensitivity of the metal oxide-based gas sensor devices. Carbon nanotubes coated with metal oxides (e.g. VOx) that can intercalate ions (e. g. Li+) can be used as cathode materials in batteries. Furthermore, carbon nanotubes coated with high-K oxides can also be used as Field Effect Transistors (FETs).

Additionally, coatings on many other different substrates may be performed. By coating organic materials in light-emitting diode (OLEDs) based devices (e.g. flat panel displays) it could be possible to expand their lifetime in protecting the organic layers from water intrusion. The skilled person will be further aware of other substrates that could benefit equally from the invention as defined herein.

Thus, the invention has been described by reference to certain embodiments discussed above. It will be recognized that these embodiments are susceptible to various modifications and alternative forms well known to those of skill in the art without departing from the spirit and scope of the invention. Accordingly, although specific embodiments have been described, these are examples only and are not limiting upon the scope of the invention.

1. A method of forming an oxide thin film on a substrate by atomic layer deposition (ALD), comprising:
providing a substrate;
exposing the substrate to a first precursor comprising a metal alkoxide or amide or heteroleptic derivatives thereof;
exposing the substrate to a second precursor comprising an ALD compatible carboxylic acid compound or derivatives thereof; and
repeating the sequential exposure to the first and second precursors until a sufficient film thickness of an oxide of the metal has been deposited on the substrate.

2. The method according to claim 1, wherein deposition takes place at a temperature of 50-450° C., preferably in the range from 150-250° C. and most preferably at around 200° C.

3. The method according to claim 1 or claim 2, wherein deposition takes place under an atmosphere of inert gas, preferably nitrogen.

4. The method according to any preceding claim, further comprising purging with a substantially inert gas between successive exposures of the substrate to the first and second precursors.

5. The method according to any preceding claim, wherein deposition takes place at a pressure of less than 20 ton, preferably around 0.2 ton.

6. The method according to any preceding claim, wherein the first precursor comprises an alkoxide of a metal selected from the group consisting of the transition metals, the lanthanides, the alkaline earth metals, Sn, In and Ga.

7. The method according to any preceding claim, wherein the second precursor comprises one or more carboxylic groups attached to hydrogen (HCOOH), an alkyl group (RCOOH), or an aryl group (ArCOOH).

8. The method according to any preceding claim, wherein exposure to the second precursor causes esterification or N-acylation.

9. The method according to any preceding claim, wherein the sequential exposure is repeated until a metal oxide film thickness of more than one metal oxide monolayer has been achieved.

10. The method according to any preceding claim, wherein exposure to the second precursor takes place substantially in the absence of water.

11. The method according to any preceding claim, further comprising finishing the component to form a micro-electronic device.

12. The method according to claim 11, wherein the finishing comprises forming a metal based gate layer over the oxide film preferably comprising tungsten nitride (WN), tantalum nitride (TaN), tantalum silicon nitride (TaSiN), titanium nitride (TiN) or polycrystalline silicon (WSi).

13. The method according to claim 11, wherein the deposition of the metal oxide film takes place at a back-end of the manufacture of the electronic device.

14. The method according to any preceding claim, wherein the substrate comprises a silicon wafer.

15. The method according to any of claims 1 to 13, wherein the substrate comprises a carbon nano-structure.

16. The method according to any preceding claim for the manufacture of an electronic component, a catalyst, a sensor, an OLED or a display panel.

17. The method according to any of claims 1 to 15 for the manufacture of a CMOS micro-electronic device.

18. The method according to any of claims 1 to 15 for the manufacture of a metal-insulator-metal (MIM) capacitor.

19. A method of manufacture of a component by atomic layer deposition (ALD) of a thin film onto a substrate, wherein at least one deposition stage comprises esterification or N-acylation.
